(19) United States
(12) Patent Application Publication
(10) Pub. No.: US 2011/0241133 A1
(43) Pub. Date: Oct. 6, 2011

(54) Semiconductor device and manufacturing method thereof

(75) Inventor: Ziyuan Liu, Kanagawa (JP)

(73) Assignee: RENESAS ELECTRONICS CORPORATION, Kawasaki (JP)

(21) Appl. No.: 13/064,483

(22) Filed: Mar. 28, 2011

(30) Foreign Application Priority Data
Mar. 30, 2010 (JP) 2010-077993

(51) Int. Cl. H01L 29/772; H01L 21/28

(52) U.S. Cl. 257/413; 438/592; 257/E29.242; 257/E21.158

(57) ABSTRACT

A semiconductor device has a gate electrode including polysilicon, and a hydrogen occluding layer covering at least a top face of the gate electrode and having a function of occluding hydrogen.

### REFERENCE TO RELATED APPLICATION

This application is based upon and claims the benefit of the priority of Japanese patent application No. 2010-077993, filed on Mar. 30, 2010, the disclosure of which is incorporated herein in its entirety by reference thereto.

### TECHNICAL FIELD

The prevent disclosure relates to a semiconductor device and manufacturing method thereof. More particularly, the prevent disclosure relates to a semiconductor device comprising a gate having polycrystalline silicon (polysilicon), and manufacturing method thereof.

### BACKGROUND

In a semiconductor device such as a semiconductor memory device, it has been reported that hydrogen which diffuses into a gate dielectric film makes a leak path and therefore increases leak current (see Non-Patent Document 1). In a process for manufacturing the semiconductor device, there are many opportunities in which hydrogen diffuses into the gate dielectric film. Therefore, in order to enhance reliability of the semiconductor device, it is necessary to restrain the diffusion of hydrogen.

It has been reported that such hydrogen may be captured by Si₂N₂O formed in an interface of SiO₂/SiN (see Non-Patent Documents 2 and 3).

Si₂N₂O is applied to a semiconductor memory device in order to restrain the diffusion of hydrogen and to enhance the reliability of the semiconductor memory device (see Patent Documents 1 and 2, for example). In a semiconductor memory device described in Patent Document 1, an insulating film is interposed between a silicon substrate and a gate electrode, the insulating film having a stack of a first silicon oxide film, a silicon nitride film and a second silicon oxide film layered in this order from the silicon substrate side, and a hydrogen occluding film is interposed on at least one or all of interfaces between the first silicon oxide film and the silicon nitride film, between the silicon nitride film and the second silicon oxide film, and between the second silicon oxide film and the gate electrode. A semiconductor memory device described in Patent Document 2 has a film which is a cover film covering a memory cell between a memory cell and an interlayer insulating film, and which has a silicon nitride film coated with hydrogen occluding films. In the semiconductor memory devices described in Patent Documents 1 and 2, a silicon nitride oxide film including Si₂N₂O is applied to the hydrogen occluding film.
[Patent Document 1]
Japanese Patent Kokai Publication No. JP-P2009-267366A
[Patent Document 2]
Japanese Patent Kokai Publication No. JP-P2009-252841A
[Non-Patent Document 1]
Nissan-Cohen, et al., “The Effect of Hydrogen on Trap Generation, Positive Charge Trapping, and Time-Dependent Dielectric Breakdown of Gate Oxides”, IEEE Electron Device Letters, Vol. 9, No. 6 287 (1988)
[Non-Patent Document 2]
Z. Liu, et al., “A hydrogen storage layer on the surface of silicon nitride films”, Applied Physics Letters, 92, 192115 (2008)
[Non-Patent Document 3]
Z. Liu, et al., “Hydrogen Distribution in Oxide-Nitride-Oxide Stacks and Correlation with Data Retention of MONOS Memories”, IEEE CFP08RPS-CDR 46^{th} Annual International Reliability Physics Symposium, 2008, 705

### SUMMARY

Above mentioned Patent and Non-Patent Documents are incorporated herein in their entirety by reference thereto. The following analysis is given from a viewpoint of the present disclosure.

In a process of forming an interlayer insulating film and a circuit of a semiconductor device, hydrogen often diffuses into a gate electrode including polysilicon. Hydrogen does not uniformly intrudes but unevenly intrudes into the gate electrode. Since the resistivity of the polysilicon gate electrode changes if hydrogen intrudes into the gate electrode, the unevenness of the hydrogen concentration in the gate electrode generates the unevenness of the resistivity of the gate electrode. With the development of miniaturization of the semiconductor device, the change in the resistivity of the polysilicon gate electrode has an influence on a characteristic of the semiconductor device now.

The layer laminated with SiO₂/SiN described in Non-Patent Documents 2 and 3 has a part which can not prevent the transmission of hydrogen and therefore can not enhance the reliability of the semiconductor device fully.

In the semiconductor memory device described in Patent Document 1, hydrogen can not be prevented from diffusing into the gate electrode. Namely, hydrogen can not be prevented from diffusing into the gate insulating film through the gate electrode.

In the semiconductor memory device described in Patent Document 2, there is possibility that hydrogen diffuses into the gate electrode when the silicon nitride film is formed because the hydrogen occluding film is formed on the surface of the silicon nitride film.

According to a first aspect of the present disclosure, there is provided a semiconductor device, which comprises a gate electrode including polysilicon, and a hydrogen occluding layer covering at least a top face of the gate electrode and having a function of occluding hydrogen.

According to a second aspect of the present disclosure, there is provided a method of manufacturing a semiconductor device, which comprises forming a gate electrode precursor-layer including polysilicon, converting at least a part of a surface of the gate electrode precursor-layer into a first oxide film, and annealing the first oxide film in an inert gas.

The meritorious effects of the present disclosure are summarized as follows.

The present disclosure has at least one of the following effects.

According to the present disclosure, hydrogen is prevented from diffusing into the gate electrode. This can maintain a certain resistivity of the gate electrode to enhance the reliability of the semiconductor device.

Hydrogen is prevented from diffusing into the gate insulation film through the gate electrode, and therefore the deterioration of the gate electrode can be suppressed. This can suppress a leak path to enhance the reliability of the semiconductor device.

### BRIEF DESCRIPTION OF THE DRAWINGS

FIG. 1 is a schematically cross-sectional view of a semiconductor device according to a first embodiment of the present disclosure.

FIG. 2 is a schematic flow chart to explain a manufacturing method of a semiconductor device according to the first embodiment.

FIG. 3 is a schematically cross-sectional view of a semiconductor device according to a second embodiment of the present disclosure.

FIG. 4 is a schematically cross-sectional view of a semiconductor device according to a third embodiment of the present disclosure.

FIG. 5 is a schematically cross-sectional view of a semiconductor device according to a fourth embodiment of the present disclosure.

FIG. 6 is a schematically cross-sectional view of a semiconductor device according to a fifth embodiment of the present disclosure.

FIG. 7 is a schematic flow chart to explain a manufacturing method of a semiconductor device according to a fifth embodiment.

### PREFERRED MODES

Preferred modes according to the first and second aspects will be mentioned below.

According to a preferred mode of the first aspect, the hydrogen occluding layer also covers side faces of the gate electrode.

According to a preferred mode of the first aspect, the hydrogen occluding layer includes a silicon oxynitride film.

According to a preferred mode of the first aspect, the hydrogen occluding layer includes the silicon oxynitride film having a composition formula of SiₓN_{y}O_{z}. A ratio of x:y:z is 1:1:0.1-0.7.

According to a preferred mode of the first aspect, the hydrogen occluding layer has a hydrogen concentration of from 3×10¹⁹ atom/cm³ to 1×10²² atom/cm³.

According to a preferred mode of the first aspect, the hydrogen occluding layer has a thickness of from 0.05 nm to 1 nm.

According to a preferred mode of the first aspect, at least a part of the gate electrode is silicified.

According to a preferred mode of the first aspect, the gate electrode and the hydrogen occluding layer are layered alternately.

According to a preferred mode of the second aspect, the method further comprises, after annealing the first oxide film, shaping the gate electrode precursor-layer into a gate electrode.

According to a preferred mode of the second aspect, the method further comprises, after shaping the gate electrode precursor-layer, converting at least a part of side faces of the gate electrode into a second oxide film, and annealing the second oxide film in an inert gas.

According to a preferred mode of the second aspect, the inert gas is nitrogen gas.

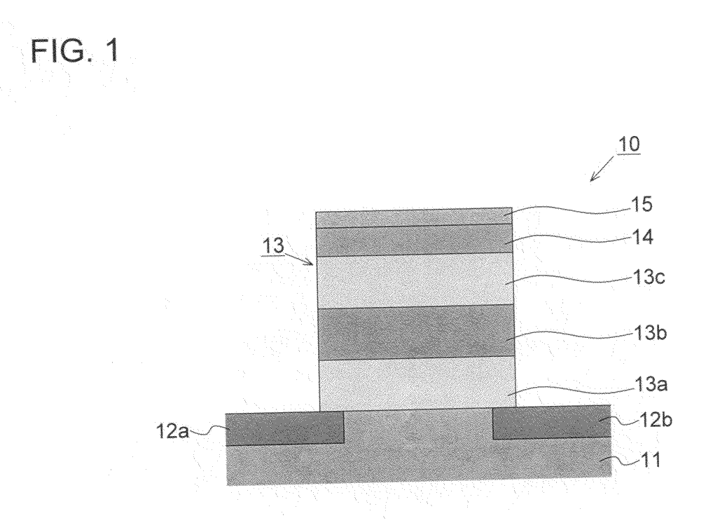

A semiconductor device according to a first embodiment of the present disclosure will be explained. FIG. 1 illustrated a schematically cross-sectional view of the semiconductor device according to the first embodiment of the present disclosure.

A semiconductor device 10 comprises a semiconductor substrate 11 in which a first diffusion region 12a and second diffusion region 12b are formed, a gate insulation film 13 formed on the semiconductor substrate 11, a gate electrode 14 formed on the gate insulation film 13, a hydrogen occluding layer 13 formed so as to cover at least a top surface of the gate electrode 14, and a insulating layer (not illustrated) formed on the semiconductor substrate 11 so as to cover layers 13-15. In the gate insulation film 13 according to the first embodiment, a first silicon oxide film 13a, silicon nitride film 13b and second silicon oxide film 13b are layered in this order. A silicon substrate may be used as the semiconductor substrate 11, for example. In the drawings, although each layer having a certain thickness is illustrated for clearness, the illustration does not necessarily reflect actual relative thicknesses.

The gate electrode 14 includes polysilicon, for example. At least a part of the gate electrode 14 may be silicified.

The hydrogen occluding layer 15 has a function that occludes or stores hydrogen. The hydrogen occluding layer 15 may be preferably a silicon oxynitride film, for example, and may be preferably a silicon oxynitride film having a composition formula of SiₓN_{y}O_{z}. The ratio of x:y:z may be preferably 1:1:0.1-0.7 and more preferably 1:1:0.4-0.5. As the hydrogen occluding layer 15, a film including Si₂N₂O may be used, for example.

The silicon oxynitride film having the composition formula of SiₓN_{y}O_{z} forms an unstable phase that is a transition phase transiting to a silicon nitride film and a silicon oxide film. Silicon in the silicon oxynitride film has a dangling bond. Hydrogen can be bonded to the dangling bond. It is presumed that the effect of occluding hydrogen in the silicon oxynitride film appears by bonding hydrogen to the dangling bond. Hydrogen bonded to the dangling bond remains in the silicon oxynitride film. Since the movement of hydrogen captured by the silicon oxynitride film is impeded, it is considered that the silicon oxynitride film displays a barrier effect that prevents hydrogen from being transmitted even when the silicon oxynitride film is exposed to a hydrogen atmosphere. Namely, the silicon oxynitride film having the occluded hydrogen has the function of capturing hydrogen and the function of the barrier. In the silicon oxynitride film having the composition formula of SiₓN_{y}O_{z}, it is considered that the dangling bond is formed in the silicon oxynitride film where the ratio of x:y:z is 1:1:0.1-0.7 and, especially, that the dangling bond is formed in a most effective way where the ratio of x:y:z is 1:1:0.4-0.5.

The hydrogen occluding layer 15 includes more hydrogen than the silicon oxide film. Since the function as the hydrogen occluding layer deteriorates if the hydrogen concentration in the hydrogen occluding layer 15 is low, it is preferred that the hydrogen concentration in the hydrogen occluding layer 15 is 3×10¹⁹ atom/cm³ or more. Since it is considered that the function as the hydrogen occluding layer deteriorates if the hydrogen concentration in the hydrogen occluding layer 15 is too high, it is preferred that the hydrogen concentration in the hydrogen occluding layer 15 is 1×10²² atom/cm³ or less and more preferably 5×10²¹ atom/cm³ or less. “Hydrogen” in this context means “hydrogen” which can be detected by the resonance nuclear reaction analysis. As a method of measuring the hydrogen concentration in the hydrogen occluding layer 15, a method using the hydrogen resonance nuclear reaction analysis described in Japanese Patent Kokai Publication No. JP-P2008-157805A may be used, for example, the entire disclosure thereof being incorporated herein by reference thereto. Provided that it is necessary that the effective thickness of the film is guaranteed by injecting ions to the silicon oxynitride film obliquely because the hydrogen occluding layer 15 according to the present disclosure preferably has a thickness of 1 nm.

In a measurement using an evaluation sample having the hydrogen occluding layer formed of the silicon oxynitride film having the thickness of 1 nm on the ONO film, where the hydrogen concentration in the hydrogen occluding layer was set to 3×10²¹ atom/cm³, the hydrogen concentration at the interface between the substrate and the ONO film could be half that of the hydrogen concentration 2×10²¹ atom/cm³. In a sample having the hydrogen concentration of 5×10²¹ atom/cm³, it was confirmed that the hydrogen concentration of the interface between the substrate and the ONO film can be suppressed further. Namely, it was confirmed that the higher the concentration of hydrogen occluded in the silicon oxynitride film is, the higher the barrier effect to hydrogen becomes. The upper limit of the preferable range of the hydrogen concentration in the hydrogen occluding layer is led to 1×10²² atom/cm³ based on atom density of the silicon oxynitride film and a hydrogen occluding mechanism. The lower limit of the preferable range of the hydrogen concentration may be higher than the concentration of hydrogen included in the bulk silicon nitride film or silicon oxide film, and may be 3×10¹⁹ atom/cm³, and more preferably 3×10²¹ atom/cm³.

The hydrogen concentration in the hydrogen occluding layer 15 can be made higher by applying heat. If the hydrogen atom concentration is made higher, the hydrogen occluding layer 15 can restrain hydrogen from permeating into the gate insulation film. The hydrogen occluding layer 15 preferably has a thickness of 0.5 nm or more. The reason is that the hydrogen occluding layer 15 needs to have at least one molecule layer of SiₓN_{y}O_{z}. The hydrogen occluding layer 15 preferably has a thickness of 1 nm or less. On the other hand, the thicker the hydrogen occluding layer 15 is, the higher the effect of the hydrogen occlusion can be made. In order to make the hydrogen occluding layer 15 thicker, an annealing process of at high temperature and for a long time is necessary. This brings about a long processing time and also an impurity profile of a well (not illustrated) formed in the substrate to be changed, counted as a problem. Therefore, the thickness of the hydrogen occluding layer 15 is preferably determined so as not to have an influence on the characteristic.

The hydrogen occluding layer 15 may be formed by making the gate electrode 14 from polysilicon, naturally oxidizing a region of the gate electrode 14 to form the hydrogen occluding layer 15, and applying an annealing process at a temperature range of 700° C. to 1150° C., preferably 900° C. to 1150° C., for 1 minute to 60 minutes in a nitrogen gas atmosphere, for example. As another method of forming the hydrogen occluding layer 15, the gate electrode is formed from polysilicon, and then a surface oxidized film is removed with hydrogen fluoride (HF). Next, without exposing the processed surface to the atmosphere, ammonia/hydrogen peroxide (APM; Ammonia hydrogen Peroxide Mixture) washing and sulfuric acid/hydrogen peroxide (SPM; Sulfuric acid-hydrogen Peroxide Mixture) washing are performed. Next, an annealing process at 600° C. to 750° C. in an atmosphere of an inert gas (nitrogen gas, for example) is applied to the washed surface.

The hydrogen occluding layer 15 can prevent hydrogen from permeating into the gate electrode 14 during the manufacturing process. This can prevent the unevenness (fluctuations) of the resistivity of the gate electrode 14. This can also prevent an impurity from diffusing into the gate insulation film 13 through the gate electrode 14.

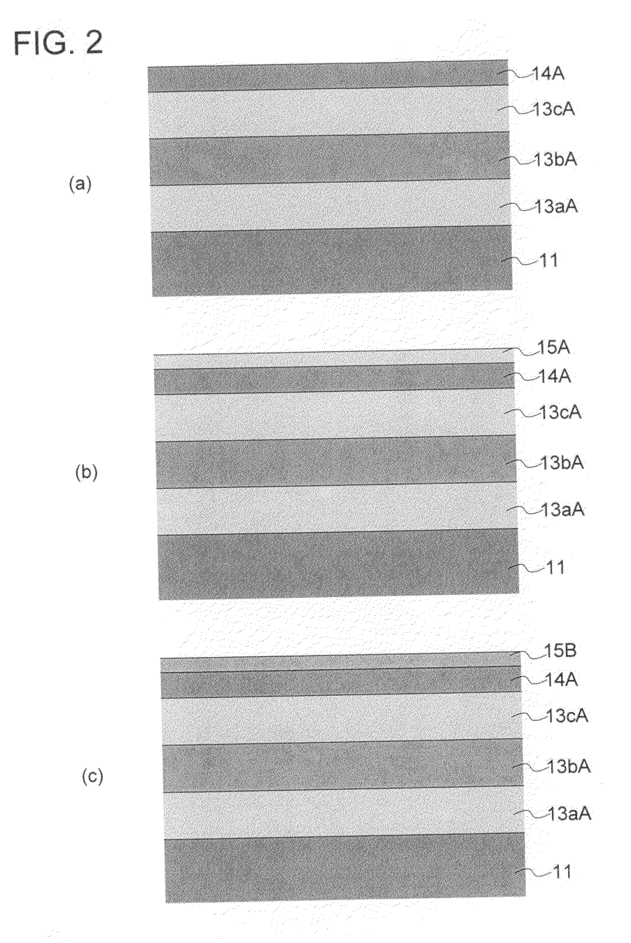

Next, a process of manufacturing the semiconductor device according to the first embodiment of the present disclosure will be explained. FIG. 2 illustrates a schematic flow to explain the process of manufacturing the semiconductor device according to the first embodiment of the present disclosure. The following explanation explains an example that a gate electrode 14 is made from polysilicon.

First, a surface of a semiconductor substrate 11 is washed with acid to remove a naturally oxidized film of the surface of the semiconductor substrate 11. Next, on the semiconductor substrate 11, a first silicon oxide film precursor-layer 13aA, silicon nitride film precursor-layer 13bA and second silicon oxide film precursor-layer 13bA which are precursor-layers of a gate insulation film 13, and a gate electrode precursor-layer 14A made from polysilicon are formed ((a) of FIG. 2). The first silicon oxide film precursor-layer 13aA may be formed by heat oxidation of the silicon substrate 11. The film of the silicon nitride film precursor-layer 13bA may be formed by a CVD method using silane and ammonia as raw material gas, for example. The gate electrode precursor-layer 14A may be formed by a CVD method or sputter method, for example.

Next, the surface of the gate electrode precursor-layer 14A is exposed to an air. This forms a natural oxide film 15A on the gate electrode precursor-layer 14A of polysilicon ((b) of FIG. 2).

Next, an annealing process (heating process) is applied in an inert gas. The annealing condition may be set to at a heat temperature of 900° C. to 1150° C. in a nitrogen atmosphere, for example. The natural oxide film 15A may be converted into a hydrogen occluding layer precursor-layer 15B having a composition formula of SiₓN_{y}O_{z} (x:y:z=1:1:0.1-0.7) by the annealing process ((c) of FIG. 2).

Next, the first silicon oxide film precursor-layer 13aA, silicon nitride film precursor-layer 13bA, second silicon oxide film precursor-layer 13bA, gate electrode precursor-layer 14A and hydrogen occluding layer precursor-layer 15B are shaped into the gate electrode. The processing may be performed by dry etching after forming a hard mask and resist mask having a certain pattern.

Next, a first diffusion region 12a and second diffusion region 12b are formed in the semiconductor substrate 11 by an ion injection using a gate structure as a mask. A semiconductor device 10 can be manufactured (FIG. 1).

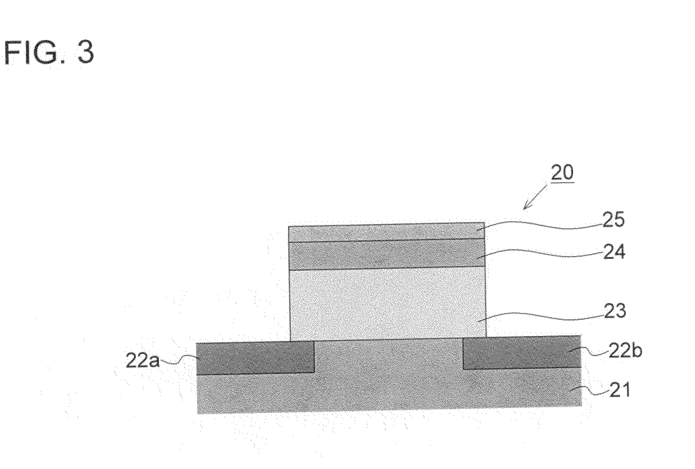

A semiconductor device according to a second embodiment of the present disclosure will be explained. FIG. 3 illustrates a schematically cross-sectional view of the semiconductor device according to the second embodiment of the present disclosure.

In the second embodiment, the gate insulation film 23 does not have the gate stack structure having the oxide film/nitride film/oxide film (ONO) but has only one layer (only the silicon oxide film, for example). The other modes are equivalent to those of the first embodiment.

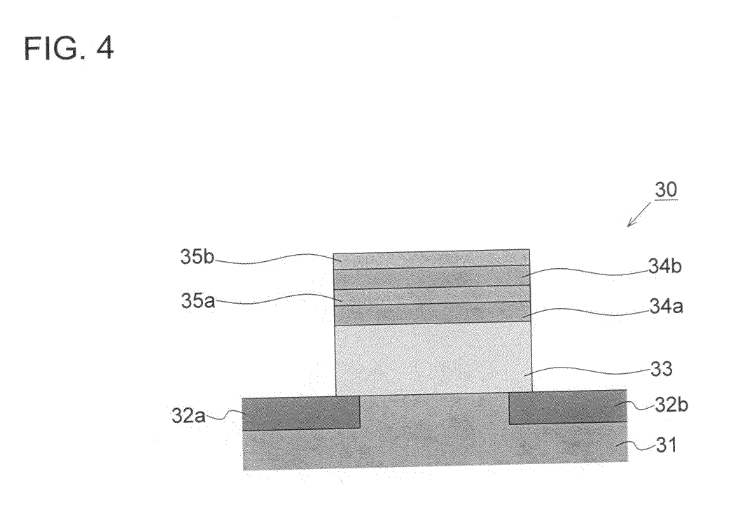

A semiconductor device according to a third embodiment of the present disclosure will be explained. FIG. 4 illustrates a schematically cross-sectional view of the semiconductor device according to the third embodiment of the present disclosure.

In the third embodiment, a plurality of hydrogen occluding layers 35a, 35b are layered. The first hydrogen occluding layer 35a is formed on a first gate electrode 34a and, on the laminate, a laminate of a second gate electrode 34b and second hydrogen occluding layer 35b is layered. The other modes are equivalent to those of the first embodiment.

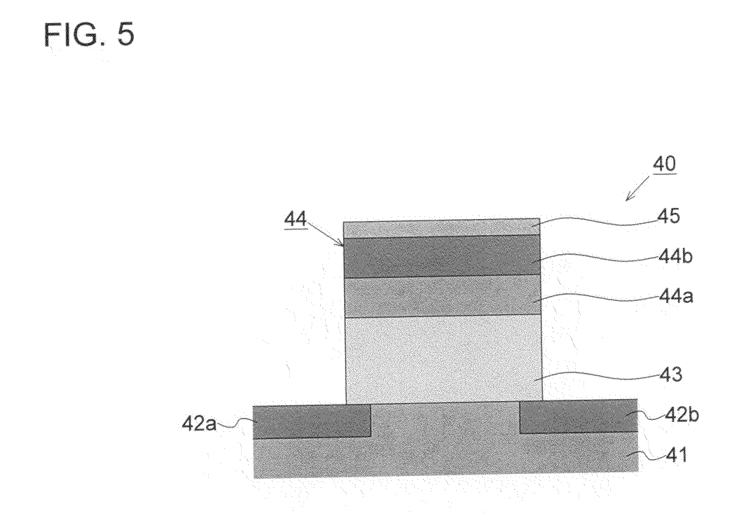

A semiconductor device according to a fourth embodiment of the present disclosure will be explained. FIG. 5 illustrates a schematically cross-sectional view of the semiconductor device according to the fourth embodiment of the present disclosure.

In the fourth embodiment, a gate electrode has a polysilicon layer 44a and a silicide layer 44b formed by silicifying a top surface of polysilicon. A hydrogen occluding layer 45 is formed so as to cover a top surface of the silicide layer 44b. The other modes are equivalent to those of the first embodiment.

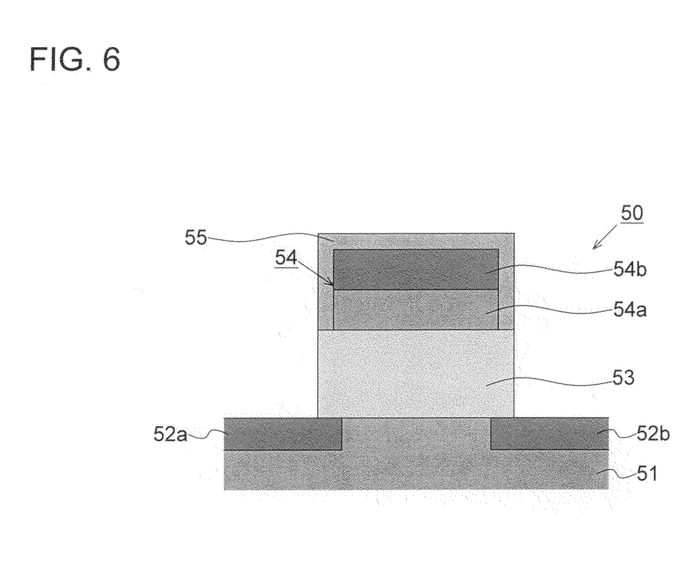

A semiconductor device according to a fifth embodiment of the present disclosure will be explained. FIG. 6 illustrates a schematically cross-sectional view of the semiconductor device according to the fifth embodiment of the present disclosure.

In the fifth embodiment, a hydrogen occluding layer is formed on both side faces of a gate electrode in the semiconductor device according to the fourth embodiment. Namely, the hydrogen occluding layer 55 is formed so as to cover both side faces and top face of the gate electrode 54. The other modes are equivalent to those of the first embodiment. According to the fifth embodiment, hydrogen is restrained from permeating from the side faces of the gate electrode.

The shorter the gate length becomes, that is, the smaller the semiconductor device becomes, the greater an influence of high resistance of the gate electrode 54 caused by hydrogen that permeates from the side faces of the gate electrode 54 becomes. The reason is that, even if the permeation depth of hydrogen is shallow, a proportion of a region having high resistance becomes greater if the gate length is short. According to the fifth embodiment, deterioration in the characteristic of the semiconductor device can be restrained even if the semiconductor device becomes small.

A method of manufacturing the hydrogen occluding layer according to the second to fifth embodiments may be same as the first embodiment. Namely, the natural oxide film of the gate electrode precursor-layer is formed in the region to form the hydrogen occluding layer, and then the hydrogen occluding layer may be formed by annealing the natural oxide film.

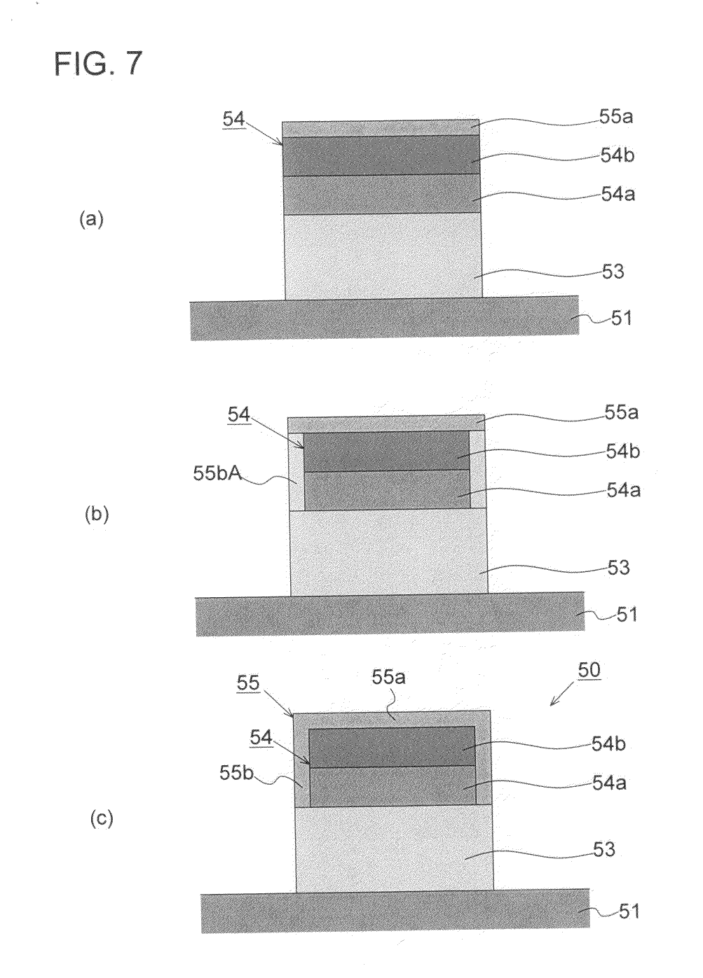

FIG. 7 illustrates a schematic flow to explain the process of manufacturing the semiconductor device according to the fifth embodiment of the present disclosure. In the fifth embodiment, in the same way as the first embodiment (FIG. 2), a first natural oxide film is formed in the top face of the gate electrode precursor-layer, and then a first hydrogen occluding layer precursor-layer is formed by annealing the first natural oxide film. Next, the gate electrode precursor-layer is shaped into the gate electrode to form a gate electrode 54 ((a) of FIG. 7). In this state, the gate electrode 54 and others become same as the fourth embodiment and has the state that the first hydrogen occluding layer 55a is formed on the top face. Next, the side faces (which are newly exposed face) of the gate electrode 54 are exposed to the air to form second natural oxide layers 55bA in the side faces of the gate electrode 54 ((b) of FIG. 7). Next, the second natural oxide films 55bA are annealed to form second hydrogen occluding films 55b in the regions of the side faces of the gate electrode 54 ((c) of FIG. 7). A semiconductor device 50 having the hydrogen occluding layer in the top face and side faces of the gate electrode 54 can be manufactured.

A semiconductor device and manufacturing method thereof of the present disclosure have been described based on the abovementioned embodiments, but there is no limitation to the abovementioned embodiments, and clearly various changes, modifications, improvements, and the like within the scope of the disclosure may be included. Furthermore, various combinations, substitutions and selections of disclosed elements are possible within the scope of the present disclosure.

Further problems, objects and developed modes of the present disclosure will become apparent from the entire disclosed matter of the present disclosure including the claims.

A semiconductor device and manufacturing method thereof of the present disclosure may be applied to various semiconductor devices such as a semiconductor device having a MOS transistor, a semiconductor memory device such as a nonvolatile memory, or the like.

It should be noted that other objects, features and aspects of the present disclosure will become apparent in the entire disclosure and that modifications may be done without departing the gist and scope of the present disclosure as disclosed herein and claimed as appended herewith.

Also it should be noted that any combination or selection of the disclosed and/or claimed elements, matters and/or items may fall under the modifications aforementioned.

What is claimed is:

1. A semiconductor device comprising:
a gate electrode including polysilicon; and
a hydrogen occluding layer covering at least a top face of said gate electrode and having a function of occluding hydrogen.

2. The semiconductor device according to claim 1, wherein
said hydrogen occluding layer also covers side faces of said gate electrode.

3. The semiconductor device according to claim 1, wherein
said hydrogen occluding layer includes a silicon oxynitride film.

4. The semiconductor device according to claim 3, wherein
said hydrogen occluding layer includes the silicon oxynitride film having a composition formula of SiₓN_{y}O_{z}, where
a ratio of x:y:z is 1:1:0.1-0.7.

5. The semiconductor device according to claim 1, wherein
said hydrogen occluding layer has a hydrogen concentration of from 3×10¹⁹ atom/cm³ to 1×10²² atom/cm³.

6. The semiconductor device according to claim 1, wherein
said hydrogen occluding layer has a thickness of from 0.05 nm to 1 nm.

7. The semiconductor device according to claim 1, wherein
at least a part of said gate electrode is silicified.

8. The semiconductor device according to claim 1, wherein
said gate electrode and said hydrogen occluding layer are layered alternately.

9. A method of manufacturing a semiconductor device comprising:
forming a gate electrode precursor-layer including polysilicon;
converting at least a part of a surface of said gate electrode precursor-layer into a first oxide film; and
annealing said first oxide film in an inert gas.

10. The method according to claim 9 further comprising:
after annealing said first oxide film,
shaping said gate electrode precursor-layer into a gate electrode.

11. The method according to claim 10 further comprising:
after shaping said gate electrode precursor-layer,
converting at least a part of side faces of said gate electrode into a second oxide film; and
annealing said second oxide film in an inert gas.

12. The method according to claim 9, wherein
said inert gas comprises nitrogen gas.
